(19) United States
(12) Patent Application Publication
(10) Pub. No.: US 2026/0204309 A1
(43) Pub. Date: Jul. 16, 2026

(54) MEMORY DEVICE INCLUDING NOISE REMOVAL CIRCUIT AND METHOD FOR OPERATING THE MEMORY DEVICE

(71) Applicant: SAMSUNG ELECTRONICS CO., LTD., Suwon-si (KR)

(72) Inventors: Hong SHIM, Suwon-si (KR); Jongpil SON, Suwon-si (KR)

(73) Assignee: SAMSUNG ELECTRONICS CO., LTD., Suwon-si (KR)

(21) Appl. No.: 19/265,749

(22) Filed: Jul. 10, 2025

(30) Foreign Application Priority Data
Jan. 15, 2025 (KR) 10-2025-0006166

(51) Int. Cl. G11C 11/408; G11C 11/4076

(52) U.S. Cl. CPC G11C 11/4082; G11C 11/4076

(57) ABSTRACT

According to an aspect of the present disclosure, a memory device includes a first buffer configured to store input temperature data for a memory cell as first temperature data based on a clock signal, and to output the first temperature data, a second buffer configured to receive and to store the first temperature data from the first buffer based on the clock signal, and to output the first temperature data as second temperature data, a delay circuit configured to output a delayed clock signal generated by delaying the clock signal, a third buffer configured to output inputted third temperature data as output temperature data based on the delayed clock signal, and a filter circuit configured to remove noise from the input temperature data based on the first temperature data, the second temperature data, and the third temperature data.

### CROSS-REFERENCE TO RELATED APPLICATIONS

This application claims priority under 35 U.S.C. § 119 to Korean Patent Application No. 10-2025-0006166, filed on Jan. 15, 2025, in the Korean Intellectual Property Office, the disclosure of which is incorporated by reference herein in its entirety.

### BACKGROUND

### 1. Field

The present disclosure relates generally to memory devices, and more particularly, to a memory device including a noise removal circuit and a method of operating the memory device.

### 2. Description of Related Art

Volatile memory devices may include, for example, static random access memory (SRAM) and dynamic random access memory (DRAM). In such memory devices, DRAMs in particular, it may be important to accurately determine the temperature of the memory chip. For example, calculating a refresh cycle of a DRAM memory chip, based on incorrect temperature data, may cause a malfunction of the memory cells inside the DRAM memory chip.

Recently, advances in memory device technology may have resulted in the commercialization of additional types of volatile memory devices, such as, but not limited to, high bandwidth memory (HBM). HBM may refer to memory devices in which stacks of multiple DRAM chips may operate at a relatively high bandwidth. As such, research on these types of devices may be actively being conducted. As the number of stacked DRAM memory chips increases in the HBM devices, there may be an increasing demand for removing noise in temperature data for the DRAM memory chips and/or for quickly outputting accurate temperature data.

### SUMMARY

One or more example embodiments of the present disclosure provide a memory device and a method of operating the memory device capable of removing noise from temperature data.

According to an aspect of the present disclosure, a memory device includes a first buffer configured to store input temperature data for a memory cell as first temperature data based on a clock signal, and to output the first temperature data, a second buffer configured to receive and to store the first temperature data from the first buffer based on the clock signal, and to output the first temperature data as second temperature data, a delay circuit configured to output a delayed clock signal generated by delaying the clock signal, a third buffer configured to output inputted third temperature data as output temperature data based on the delayed clock signal, and a filter circuit configured to remove noise from the input temperature data based on the first temperature data, the second temperature data, and the third temperature data.

According to an aspect of the present disclosure, a method of operating a memory device includes storing, as first temperature data in a first buffer, previous output temperature data for a memory cell, storing, as second temperature data in a second buffer, first input temperature data of the memory cell inputted during a first period of a clock signal, storing, as third temperature data in a third buffer, second input temperature data of the memory cell inputted during a second period subsequent to the first period of the clock signal, comparing a first magnitude of the first temperature data, a second magnitude of the second temperature data, and a third magnitude of the third temperature data, outputting a selection signal based on the comparing, and outputting, as current output temperature data, at least one of the first temperature data or the third temperature data based on the selection signal, the current output temperature data being synchronized to a delayed clock signal generated by delaying the clock signal.

According to an aspect of the present disclosure, a memory device includes a memory die including a plurality of memory cells, and a noise removal circuit configured to compare a third magnitude of previous output temperature data of the plurality of memory cells, a first magnitude of first input temperature data of the plurality of memory cells inputted during a first period of a clock signal, and a second magnitude of second input temperature data of the plurality of memory cells inputted during a second period subsequent to the first period of the clock signal, and output, as current output temperature data of the plurality of memory cells, at least one of the previous output temperature data or the second input temperature data, based on a delayed clock signal generated by delaying the clock signal, and a logic die stacked with the memory die in a first direction and configured to control a temperature of the memory die based on the current output temperature data provided using a through-silicon via at least partially penetrating the memory die in the first direction.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a block diagram of a memory system, according to an embodiment of the present disclosure;

FIG. 2 is a diagram of a memory system, according to an embodiment of the present disclosure;

FIG. 3 is a block diagram of a memory device, according to an embodiment of the present disclosure;

FIG. 4 is a block diagram of a memory device, according to an embodiment of the present disclosure;

FIG. 5 is a diagram of the operation of a memory device, according to an embodiment of the present disclosure;

FIG. 6 is a timing diagram of the operation of a memory device, according to an embodiment of the present disclosure;

FIG. 7 is a flowchart of the operation of a memory device, according to an embodiment of the present disclosure;

FIG. 8 is a perspective view of a semiconductor device, according to an embodiment of the present disclosure;

FIG. 9 is a perspective view of a semiconductor device, according to an embodiment of the present disclosure; and

FIG. 10 is a block diagram of a computing device, according to an embodiment of the present disclosure.

### DETAILED DESCRIPTION

In the following description, only certain embodiments of the present disclosure have been shown and described, simply by way of illustration. Those skilled in the art may recognize that the described embodiments may be modified in various different ways, without departing from the spirit or scope of the present disclosure.

Accordingly, the drawings and description are to be regarded as illustrative in nature and not restrictive. Like reference numerals designate like elements throughout the specification. In the flow charts described with reference to the drawings, the order of operations may be changed, and several operations may be combined, and an operation may be divided, and some operations may not be performed.

Further, expressions written in the singular forms may be comprehended as the singular forms or plural forms unless clear expressions such as “a”, “an”, or “single” may be used. Terms including an ordinal number, such as first and second, may be used for describing various constituent elements, but the constituent elements may not be limited by the terms. These terms may be used only to discriminate one constituent element from other constituent elements.

As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein may be example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” may be intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, various embodiments of the present disclosure are described through examples and with reference to the accompanying drawings. These examples are intended to illustrate the present disclosure, and the right protection scope of the present disclosure is not limited by these examples.

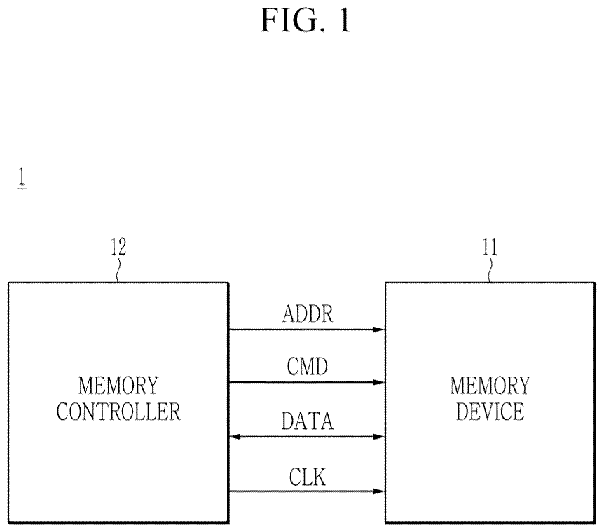

FIG. 1 is a block diagram of a memory system, according to an embodiment of the present disclosure.

Referring to FIG. 1, a memory system 1 may include a memory device 11 and a memory controller 12.

The memory device 11 may operate under the control of the memory controller 12. The memory device 11 may be and/or may include a volatile memory device such as, but not limited to, static random access memory (SRAM), dynamic random access memory (DRAM), or the like.

Alternatively, the memory device 11 may be and/or may include a nonvolatile memory device such as, but not limited to, NAND flash memory, vertical NAND (VNAND) flash memory, bonding vertical NAND (BVNAND) flash memory, NOR flash memory, resistive random access memory (RRAM), phase-change RAM (PRAM), magneto-resistive RAM (MRAM), ferroelectric RAM (FRAM), spin transfer torque RAM (STT-RAM), conductive bridging RAM (CBRAM), or the like.

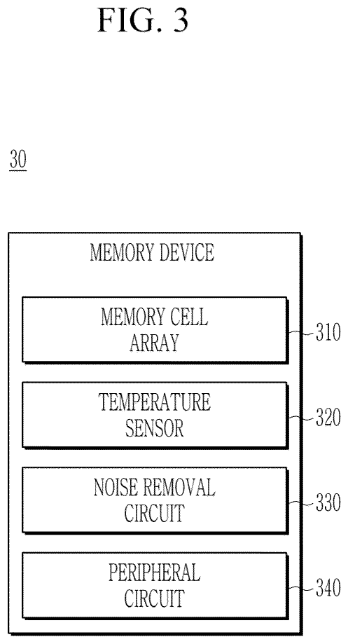

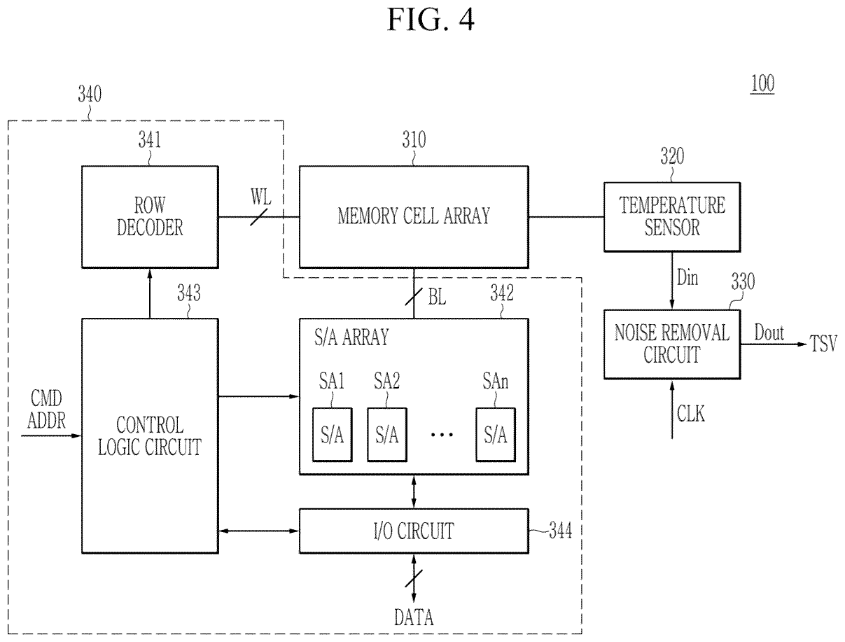

In the following description, the memory device 11 may be described as being a DRAM. However, embodiments of the present disclosure may not necessarily be limited thereto, and the memory device 11 may be implemented as various types of memory devices other than a DRAM. The configuration of the memory device 11 is described with reference to FIGS. 3 and 4.

The memory controller 12 may be configured to access the memory device 11 in response to a request from a host device. A memory controller 12 may be configured to provide an interface between a memory device 11 and a host device. Additionally, the memory controller 12 may be configured to drive firmware for controlling the memory device 11.

The memory controller 12 may control the operation of the memory device 11. For example, the memory controller 12 may provide at least one of an address ADDR, a command CMD, data, and a clock signal CLK along an input/output line connected to the memory device 11.

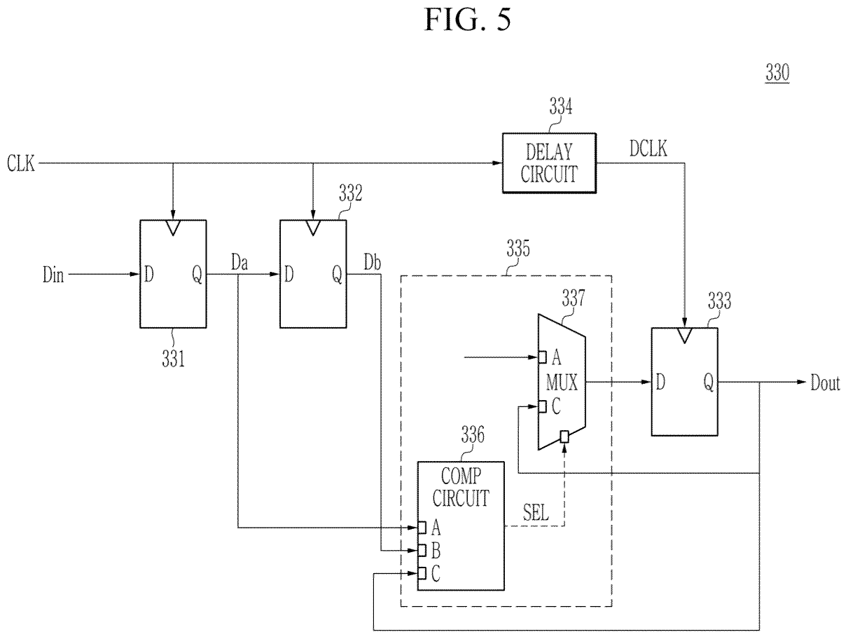

The memory controller 12 may write data to the memory device 11, erase data of the memory device 11, and/or read data from the memory device 11 based on an address ADDR, a command CMD, and a clock signal CLK. The memory device 11 may remove noise of temperature data for the memory device 11 based on a clock signal CLK from the memory controller 12, as described below with reference to FIG. 5.

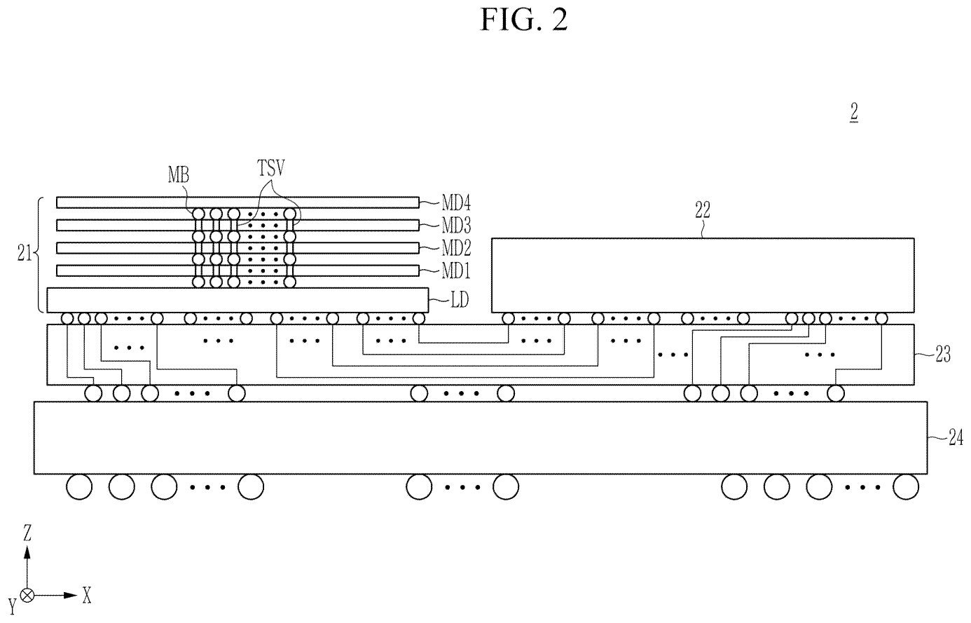

FIG. 2 is a diagram of a memory system, according to an embodiment of the present disclosure.

Referring to FIG. 2, the memory system 2 may include a memory device 21, a host device 22, an interposer 23, and a printed circuit board (PCB) 24. The memory system 2 may include and/or may be similar in many respects to the memory system 1 described above with reference to FIG. 1, and may include additional features not mentioned above. Consequently, repeated descriptions of the memory system 2 described above with reference to FIG. 1 may be omitted for the sake of brevity.

The memory device 21 may include a plurality of memory dies (e.g., a first memory die MD1, a second memory die MD2, a third memory die MD3, and a fourth memory die MD4) and a logic die LD stacked in the first direction Z. A plurality of bumps MB may be formed between the stacked memory dies MD1 to MD4 and the logic die LD, and a through silicon via TSV penetrating the memory dies MD1 to MD4 may be formed between the stacked plurality of bumps MB. The plurality of bumps MB may be arranged on the lower surface of the logic die LD based on the first direction Z.

Each of the memory dies MD1 to MD4 may be and/or may include a high bandwidth memory (HBM) DRAM die. However, embodiments of the present disclosure may not necessarily be limited thereto. Each of the memory dies MD1 to MD4 may include a plurality of memory cells for storing data, a temperature sensor for measuring the temperature of the plurality of memory cells, a noise removal circuit for removing noise from the temperature data, and peripheral circuits for reading and/or writing data to the plurality of memory cells.

For each of the memory dies MD1 to MD4, noise-removed temperature data may be transmitted to the logic die LD through through-silicon via TSV. The logic die LD may transmit a control signal to each of the memory dies MD1 to MD4 to control the temperature of the memory dies MD1 to MD4 based on the temperature data of each of the provided memory dies MD1 to MD4. The through silicon via TSV through which the temperature data may be transmitted and the through silicon via TSV through which the control signals may be transmitted may be the same. Alternatively, in some embodiments, the temperature data and the control signals may be transmitted respectively through different through silicon via TSV.

Although FIG. 2 depicts the memory device 21 as including four (4) stacked memory dies MD1 to MD4 and the logic die LD being positioned below the stacked memory dies MD1 to MD4, embodiments of the present disclosure may not necessarily be limited thereto. For example, the memory device 21 may include five (5) or more stacked memory dies, and the logic die LD may be stacked on top of the stacked memory dies MD1 to MD4 rather than below the stack.

Each of the memory dies MD1 to MD4 illustrated in FIG. 2 may be manufactured as a memory device that may store data input through data terminals into selected memory cells from among a plurality of memory cells of a memory cell array in response to commands and/or addresses applied through command and/or address terminals, and/or may output data stored in the selected memory cells through data terminals.

A plurality of bumps MB may be arranged on the lower surface of the host device 22, and the plurality of bumps MB may be and/or may include micro bumps. A plurality of bumps MB may be arranged on the lower surface of the interposer 23, and the interposer 23 may include command and address lines and control signal lines connecting the plurality of bumps MB. A plurality of balls may be arranged on the lower surface of the PCB 24, and a plurality of bumps MB and a plurality of balls may be connected on the PCB 24.

FIGS. 3 and 4 are block diagrams of a memory device, according to an embodiment of the present disclosure.

Referring to FIGS. 3 and 4, the memory device 30 may include a memory cell array 310, a temperature sensor 320, a noise removal circuit 330, and a peripheral circuit 340. The peripheral circuit 340 may include a row decoder 341, a sense amplifier array 342, a control logic circuit 343, and an input/output (I/O) circuit 344.

The memory cell array 310 may include a plurality of memory cells arranged in the row direction and the column direction. A plurality of memory cells may be connected to a plurality of word lines WL extending in the row direction and a plurality of bit lines BL extending in the column direction.

For ease of description, an embodiment in which each of the plurality of memory cells may be a dynamic random access memory cell is described below as a representative example. However, embodiments of the present disclosure may not necessarily be limited thereto, and each of the plurality of memory cells may be and/or may include any type of volatile memory cell, such as, but not limited to, a static random access memory cell, or any type of non-volatile memory cell, such as, but not limited to, a flash memory cell. That is, the scope of the present disclosure is not limited to the type of memory device 30.

The temperature sensor 320 may measure the temperature of the memory cell array 310. The temperature sensor 320 may output the measured temperature of the memory cell array 310 as temperature data Din to the noise removal circuit 330. The temperature of the memory cell array 310 measured by the temperature sensor 320 may also be referred to as the measured temperature of the memory device 30. Temperature data Din output from the temperature sensor 320 to the noise removal circuit 330 may be referred to as input temperature data hereinafter.

The noise removal circuit 330 may remove noise of input temperature data Din, for example, based on a clock signal CLK provided from a memory controller 12 in FIG. 1. The noise removal circuit 330 may output temperature data with noise removed from the input temperature data Din. Temperature data Dout output from the noise removal circuit 330 may be referred to as output temperature data hereinafter.

In some embodiments, the memory device 30 may further include a clock division circuit. In this case, the clock division circuit may divide the clock signal CLK provided from the memory controller 12 and provide the divided clock signal to the noise removal circuit 330. The noise removal circuit 330 may remove noise from the input temperature data Din based on the corresponding clock signal.

Alternatively, in some other embodiments, the memory device 30 may further include a clock generation circuit. In this case, the clock generation circuit may provide the generated clock signal CLK to the noise removal circuit 330. The noise removal circuit 330 may also remove noise from the input temperature data Din based on the corresponding clock signal CLK.

The noise removal circuit 330 may output temperature data Dout through a through silicon via TSV. That is, as described with reference to FIG. 2, each of the memory dies MD1 to MD4 may include a memory cell array 310, a temperature sensor 320, and a noise removal circuit 330, and each of the memory dies MD1 to MD4 may provide output temperature data Dout with noise removed through the noise removal circuit 330 to a logic die LD through a through-silicon via TSV. Based on the output temperature data Dout for each memory die MD1 to MD4 provided through the through silicon via TSV, the logic die LD may control the temperature of each memory die MD1 to MD4.

A row decoder 341 may control a plurality of word lines WL. For example, the row decoder 341 may activate some of the plurality of word lines WL based on an address ADDR provided to the control logic circuit 343.

The sense amplifier array 342 may include a plurality of sense amplifiers S/A. For example, the sense amplifier array 342 may include a first sense amplifier SA1, a second sense amplifier SA2, to an n-th sense amplifier SAn, where n is a positive integer greater than one (1).

Each of the multiple sense amplifiers SA may be connected to a plurality of bit lines BL. For example, each of the plurality of sense amplifiers SA may be connected to a bit line and a complementary bit line. Each of the plurality of sense amplifiers SA may detect and/or amplify a change in the voltage level of a connected bit line BL based on a voltage level difference between the connected bit line and the complementary bit line.

The control logic circuit 343 may receive a command CMD and an address ADDR (e.g., from a memory controller 12 in FIG. 1). The control logic circuit 343 may control operations of the memory device 30 based on a command CMD and/or an address ADDR.

In some embodiments, the control logic circuit 343 may provide a plurality of control signals to the sense amplifier array 342. For example, the control logic circuit 343 may provide a plurality of control signals to the sense amplifier array 342 to control the operation of each of the plurality of sense amplifiers SA. However, embodiments of the present disclosure may not be limited thereto.

The I/O circuit 344 may output data DATA corresponding to a change in the voltage level of a bit line BL amplified by the sense amplifier array 342 to the outside and/or receive data DATA from the outside.

FIG. 5 is a diagram of the operation of a memory device, according to an embodiment of the present disclosure. Referring to FIG. 5, a diagram of the operation of a noise removal circuit 330 included in a memory device, according to an embodiment of the present disclosure, is illustrated.

As shown in FIG. 5, the noise removal circuit 330 may include a first buffer 331, a second buffer 332, a third buffer 333, a delay circuit 334, and a filter circuit 335. The filter circuit 335 may include a comparison circuit 336 and a multiplexer 337.

The first buffer 331 may receive input temperature data Din. The first buffer 331 may receive input temperature data Din from, for example, a temperature sensor 320 in FIG. 4. The first buffer 331 may store the provided input temperature data Din as first temperature data. The first buffer 331 may output the stored input temperature data Din as first temperature data Da based on a clock signal CLK.

The second buffer 332 may receive first temperature data Da. The second buffer 332 may receive first temperature data Da from the first buffer 331, for example. The second buffer 332 may store the provided first temperature data Da as second temperature data Db. The second buffer 332 may output the stored first temperature data Da as second temperature data Db based on the clock signal CLK.

The first buffer 331 and the second buffer 332 may be implemented as flip-flops. However, embodiments of the present disclosure may not necessarily be limited thereto. For convenience of explanation, the following description may assume that the first buffer 331 and the second buffer 332 are implemented as flip-flops.

The first buffer 331 receiving input temperature data Din and outputting the input temperature data Din as first temperature data Da may be performed at different periods of the clock signal CLK. For example, the first buffer 331 may receive and store input temperature data Din during the first period of the clock signal CLK, and output the input temperature data Din as first temperature data Da during the second period subsequent to the first period of the clock signal CLK.

Additionally, the second buffer 332 receiving the first temperature data Da and outputting the first temperature data Da as the second temperature data Db may be performed at different period of the clock signal CLK. For example, the second buffer 332 may receive and store the first temperature data Da outputted from the first buffer 331 during the second period of the clock signal CLK, and may output the first temperature data Da as the second temperature data Db during the third period subsequent to the second period of the clock signal CLK.

The first temperature data Da outputted from the first buffer 331 may be input to the A terminal of the comparison circuit 336 and the A terminal of the multiplexer 337. The second temperature data Db output from the second buffer 332 may be input to the B terminal of the comparison circuit 336.

The third buffer 333 may receive temperature data from the multiplexer 337. For convenience of explanation, the temperature data provided to the third buffer 333 from the multiplexer 337 may also be referred to as third temperature data.

The third buffer 333 may store the provided third temperature data and output the stored third temperature data as output temperature data Dout based on the delay clock signal DCLK. The third buffer 333 may output the output temperature data Dout to a through-silicon via (e.g., TSV of FIGS. 2 and 4). Additionally, the output temperature data Dout outputted from the third buffer 333 may be input to the C terminal of the comparison circuit 336 and the C terminal of the multiplexer 337.

The third buffer 333 may be implemented as a latch. However, embodiments of the present disclosure may not necessarily be limited thereto. For convenience of explanation, the following description may assume that the third buffer 333 is implemented as a latch.

In an embodiment, the input temperature data Din, the first temperature data Da, the second temperature data Db, and the output temperature data Dout may have a size of eight (8) bits. In some embodiments, if one (1) bit represents a size of 1° C., the temperature data may express a temperature in the range of 256° C. In some other embodiments, if one (1) bit represents a size of 0.5° C., the temperature data may express a temperature in the range of 512° C.

However, the above examples are only for convenience of explanation, and the embodiments are not necessarily limited thereto. The temperature data corresponding to the temperature of the memory device 30 in FIG. 3 or the memory cell array 310 in FIG. 3 measured from the temperature sensor 320 in FIG. 3 may have various sizes depending on the implementation method.

The delay circuit 334 may delay the phase of a clock signal CLK provided from, for example, a memory controller 12 in FIG. 1. The delay circuit 334 may delay the phase of the clock signal CLK to output a delayed clock signal DCLK. The delay circuit 334 may provide a delay clock signal DCLK to the third buffer 333. The delay circuit 334 may delay the clock signal CLK within a half period of the clock signal CLK.

For example, if a clock signal CLK has a rising edge at a first time point and a falling edge at a second time point following the first time point, the delay circuit 334 may output a delayed clock signal DCLK that has a rising edge between the first time point and the second time point and a falling edge at any time point after the second time point.

The filter circuit 335 may remove noise from input temperature data Din based on first temperature data Da, second temperature data Db, and output temperature data Dout.

The comparison circuit 336 may receive first temperature data Da, second temperature data Db, and output temperature data Dout through terminals A to C. The comparison circuit 336 may compare the magnitudes of the first temperature data Da, the second temperature data Db, and the output temperature data Dout. The comparison circuit 336 may output a selection signal SEL based on the comparison result and provide the selection signal SEL to a multiplexer 337.

That is, the comparison circuit 336 may compare the magnitudes of the first temperature data Da and the second temperature data Db, and subsequently compare the magnitudes of the first temperature data Da and the output temperature data Dout. The comparison circuit 336 may determine whether the difference between the magnitudes of the first temperature data Da and the second temperature data Db and the difference between the magnitudes of the first temperature data Da and the output temperature data Dout may be within a predetermined threshold value. For example, the predetermined threshold value may have a size of four (4) bits. However, embodiments of the present disclosure may not necessarily be limited thereto.

The comparison circuit 336 may output a selection signal SEL of low level (e.g., logic ‘0’) when the difference between the magnitudes of the first temperature data Da and the second temperature data Db is less than or equal to a predetermined threshold value. The comparison circuit 336 may subsequently compare the magnitudes of the first temperature data Da and the output temperature data Dout when the difference between the magnitudes of the first temperature data Da and the second temperature data Db is greater than a predetermined threshold value.

The comparison circuit 336 may output a low level selection signal SEL when the difference between the magnitudes of the first temperature data Da and the output temperature data Dout is less than or equal to a predetermined threshold value. The comparison circuit 336 may output a selection signal SEL of a high level (e.g., logic ‘1’) when the difference between the magnitudes of the first temperature data Da and the output temperature data Dout is greater than a predetermined threshold value.

When the signal level of the selection signal SEL corresponds to a low level, the multiplexer 337 may output the first temperature data Da from among the input first temperature data Da and the output temperature data Dout as the third temperature data to the third buffer 333. When the signal level of the selection signal SEL corresponds to a high level, the multiplexer 337 may output the output temperature data Dout from among the input first temperature data Da and the output temperature data Dout as third temperature data to the third buffer 333.

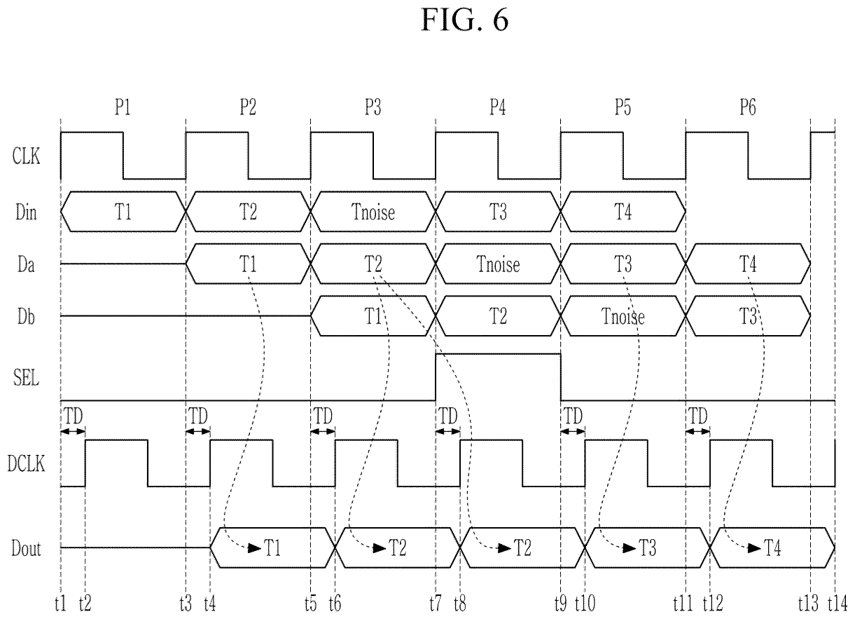

FIG. 6 is a timing diagram of the operation of a memory device, according to an embodiment of the present disclosure.

Referring to FIG. 6, a clock signal CLK may have a first period P1 between a first time point t1 and a third time point t3, a second period P2 between a third time point t3 and a fifth time point t5, a third period P3 between a fifth time point t5 and a seventh time point t7, a fourth period P4 between a seventh time point t7 and a ninth time point t9, a fifth period P5 between a ninth time point t9 and an eleventh time point t11, and a sixth period P6 between an eleventh time point t11 and a thirteenth time point t13.

The delayed clock signal DCLK may have a phase delay with respect to the clock signal CLK that may have been generated by the delay circuit 334 in FIG. 5. The delay time TD by which the clock signal CLK may be delayed may be within half a period of the clock signal CLK. Taking the first period P1 of the clock signal CLK as an example, the delay time TD may be less than half the time difference between the third time point t3 and the first time point t1.

The input temperature data Din of T1 may be input into the first buffer 331 in FIG. 5 during the first period P1 of the clock signal CLK. The first buffer 331 may store the input temperature data Din of T1 inputted during the first period P1.

During the first period P1, the first temperature data Da, the second temperature data Db, and the output temperature data Dout may not be output, and in this case, the comparison circuit 336 in FIG. 5 may output a low-level selection signal SEL. That is, the comparison circuit 336 may output a low level selection signal SEL between the first time point t1 and the third time point t3.

During the second period P2 subsequent to the first period P1 of the clock signal CLK, the first buffer 331 may output the stored input temperature data Din of T1 as first temperature data Da. The first buffer 331 may receive input temperature data Din of T2, which may be different from T1, during the second period P2, and store the input temperature data Din of T2 during the second period P2.

During the second period P2 of the clock signal CLK, the first temperature data Da of T1 output from the first buffer 331 may be provided to the second buffer 332 of FIG. 5. The second buffer 332 may store the first temperature data Da of the input T2 during the second period P2.

During the second period P2, only the first temperature data Da may be output to the comparison circuit 336 and the multiplexer 337 in FIG. 5. In this case, the comparison circuit 336 may output a low level selection signal SEL. That is, the comparison circuit 336 may output a low level selection signal SEL between the third time point t3 and the fifth time point t5.

In response, the multiplexer 337 may output the first temperature data Da as third temperature data to the third buffer 333 in FIG. 5. The third buffer 333 may output the first temperature data Da of T1 as output temperature data Dout between the fourth time point t4 and the sixth time point t6 of the delayed clock signal DCLK delayed by the second period P2 of the clock signal CLK.

During the third period P3 subsequent to the second period P2 of the clock signal CLK, the first buffer 331 may output the stored input temperature data Din of T2 as first temperature data Da. The first buffer 331 may receive input temperature data Din of Tnoise different from T2 during the third period P3 and store the input temperature data Din of Tnoise during the third period P3. As used herein, Tnoise may refer to input temperature data Din that may include noise.

During the third period P3 of the clock signal CLK, the second buffer 332 may output the stored first temperature data Da of T1 as second temperature data Db. During the third period P3, the first temperature data Da of T2 output from the first buffer 331 may be provided to the second buffer 332. The second buffer 332 may store the first temperature data Da of the input T2 during the third period P3.

In the third period P3, the comparison circuit 336 may compare the magnitudes of the first temperature data Da of T2, the second temperature data Db of T1, and the output temperature data Dout of T1. As used herein, the output temperature data Dout of T1 may be referred to as previous output temperature data in that the previous output temperature data may be the output temperature data Dout outputted between the fourth time point t4 and the sixth time point t6 of the delayed clock signal DCLK that may be delayed by the second period P2 prior to the third period P3 of the clock signal CLK currently being discussed, and the output temperature data Dout outputted between the sixth time point t6 and the eighth time point t8 of the delayed clock signal DCLK corresponding to the current third period P3 may be referred to as current output temperature data.

The comparison circuit 336 may first compare the magnitudes of the first temperature data Da of T2 and the second temperature data Db of T1. The first temperature data Da of T2 and the second temperature data Db of T1 may be data that may not contain noise, and the difference in their magnitudes may be less than a predetermined threshold value. Accordingly, the comparison circuit 336 may output a low level selection signal SEL at the fifth time point t5 and the seventh time point t7.

The multiplexer 337 may output the first temperature data Da of T2 as third temperature data to the third buffer 333 in response to a low level selection signal SEL. The third buffer 333 may output the first temperature data Da of T2 as output temperature data Dout between the sixth time point t6 and the eighth time point t8 of the delayed clock signal DCLK delayed by the third cycle P3 of the clock signal CLK.

During the fourth period P4 subsequent to the third period P3 of the clock signal CLK, the first buffer 331 may output the input temperature data Din of the stored Tnoise as the first temperature data Da. The first buffer 331 may receive input temperature data Din of T3 different from Tnoise during the fourth period P4 and store the input temperature data Din of T3 during the fourth period P4.

During the fourth period P4 of the clock signal CLK, the second buffer 332 may output the stored first temperature data Da of T2 as second temperature data Db. During the fourth period P4, the first temperature data Da of Tnoise output from the first buffer 331 may be provided to the second buffer 332. The second buffer 332 may store the first temperature data Da of the input Tnoise during the fourth period P4.

In the fourth period P4, the comparison circuit 336 may compare the magnitudes of the first temperature data Da of Tnoise, the second temperature data Db of T2, and the output temperature data Dout of T2 (e.g., the previous output temperature data).

The comparison circuit 336 may first compare the magnitudes of the first temperature data Da of Tnoise and the second temperature data Db of T2. The first temperature data Da of Tnoise may be data containing noise, and the difference between the magnitudes of the first temperature data Da of Tnoise and the second temperature data Db of T2 may be greater than a predetermined threshold value. The comparison circuit 336 may subsequently compare the magnitudes of the first temperature data Da of Tnoise and the output temperature data Dout of T2.

As described above, since the difference between the magnitudes of the first temperature data Da of Tnoise and the output temperature data Dout of T2 may be greater than a predetermined threshold value, the comparison circuit 336 may output a selection signal SEL of high level between the seventh time point t7 and the ninth time point t9 based on the comparison result.

The multiplexer 337 may output the previous output temperature data of T2 as third temperature data to the third buffer 333 in response to the selection signal SEL of high level. The third buffer 333 may re-output the previous output temperature data of T2 as the current output temperature data between the eighth time point t8 and the tenth time point t10 of the delayed clock signal DCLK delayed by the fourth period P4 of the clock signal CLK.

During the fifth period P5 subsequent to the fourth period P4 of the clock signal CLK, the first buffer 331 may output the stored input temperature data Din of T3 as first temperature data Da. The first buffer 331 may receive input temperature data Din of T4, which may be different from T3, during the fifth period P5, and store the input temperature data Din of T4 during the fifth period P5.

During the fifth period P5 of the clock signal CLK, the second buffer 332 may output the first temperature data Da of the stored Tnoise as the second temperature data Db. During the fifth cycle P5, the first temperature data Da of T3 output from the first buffer 331 may be provided to the second buffer 332. The second buffer 332 may store the first temperature data Da of the input T3 during the fifth period P5.

In the fifth period P5, the comparison circuit 336 may compare the magnitudes of the first temperature data Da of T3, the second temperature data Db of Tnoise, and the output temperature data Dout of T2 (e.g., the previous output temperature data).

The comparison circuit 336 may first compare the magnitudes of the first temperature data Da of T3 and the second temperature data Db of Tnoise. As described above, the second temperature data Db of Tnoise may be data containing noise, and the difference between the magnitudes of the first temperature data Da of T3 and the second temperature data Db of Tnoise may be greater than a predetermined threshold value. The comparison circuit 336 may subsequently compare the magnitudes of the first temperature data Da of T3 and the output temperature data Dout of T2.

The first temperature data Da of T3 and the output temperature data Dout of T2 may be data that may not contain noise, and the difference in their magnitudes may be less than a predetermined threshold value. Accordingly, the comparison circuit 336 may output a selection signal SEL of low level between the ninth time point t9 and the eleventh time point t11.

The multiplexer 337 may output the first temperature data Da of T3 as third temperature data to the third buffer 333 in response to a selection signal SEL of low level. The third buffer 333 may output the first temperature data Da of T3 as output temperature data Dout between the tenth point in time t10 and the twelfth point in time t12 of the delayed clock signal DCLK delayed by the fifth period P5 of the clock signal CLK.

During the sixth period P6 subsequent to the fifth period P5 of the clock signal CLK, the first buffer 331 may output the stored input temperature data Din of T4 as first temperature data Da.

During the sixth period P6 of the clock signal CLK, the second buffer 332 may output the stored first temperature data Da of T3 as second temperature data Db. During the sixth period P6, the first temperature data Da of T4 output from the first buffer 331 may be provided to the second buffer 332. The second buffer 332 may store the first temperature data Da of the input T4 during the sixth period P6.

In the sixth period P6, the comparison circuit 336 may compare the magnitudes of the first temperature data Da of T4, the second temperature data Db of T3, and the output temperature data Dout of T3 (e.g., the previous output temperature data).

The comparison circuit 336 may first compare the magnitudes of the first temperature data Da of T4 and the second temperature data Db of T3. The first temperature data Da of T4 and the second temperature data Db of T3 may be data that may not contain noise, and the difference in their magnitudes may be less than a predetermined threshold value. Accordingly, the comparison circuit 336 may output a selection signal SEL of low level at the eleventh time point t11 and the thirteenth time point t13.

The multiplexer 337 may output the first temperature data Da of T4 as third temperature data to the third buffer 333 in response to a selection signal SEL of low level. The third buffer 333 may output the first temperature data Da of T4 as output temperature data Dout between the twelfth point in time t12 and the fourteenth point in time t14 of the delayed clock signal DCLK delayed by the sixth period P6 of the clock signal CLK.

A memory device 30, according to an embodiment of the present disclosure, may obtain output temperature data Dout from which noise has been removed through a noise removal circuit 330 as described above. That is, even if the input temperature data Din contains noise, the output temperature data Dout with the noise removed may be obtained based on the previous input temperature data Din and the previous output temperature data that do not contain noise contained in the plurality of first to third buffers 331 to 333.

In addition, as described with reference to the third period P3 and the fourth period P4 of the clock signal CLK, by replacing the input temperature data Din of Tnoise including noise, the temperature data of T2 input later from among the temperature data of T1 and T2 may be output as the output temperature data Dout with the noise removed. That is, the memory device 30, according to an embodiment of the present disclosure, may output the temperature data most recently input at the specific point in time as the output temperature data Dout instead of the input temperature data Din including noise at a specific point in time, thereby enabling the temperature of the memory device 30 to be more accurately determined.

In addition, since the third buffer 333 outputs the output temperature data Dout based on the delay clock signal DCLK, the memory device 30, according to an embodiment of the present disclosure, may reduce the time delay between the input temperature data Din and the output temperature data Dout.

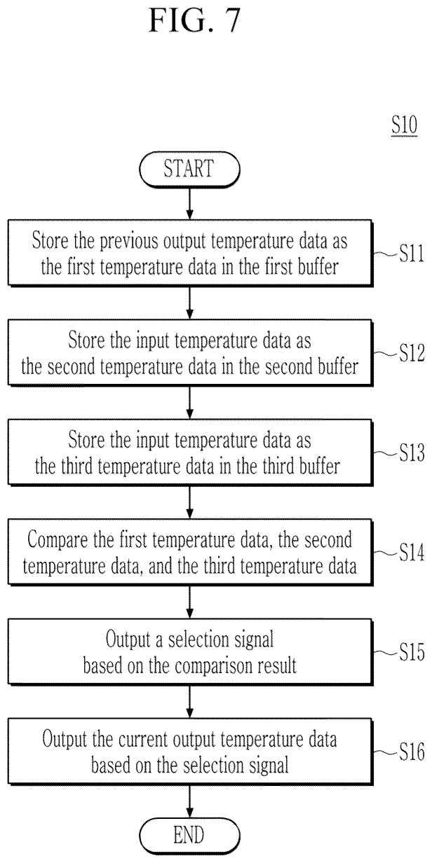

FIG. 7 is a flowchart of the operation of a memory device, according to an embodiment of the present disclosure. For convenience of explanation, the following description is made with reference to FIGS. 5 and 6.

Referring to FIGS. 5 to 7, the operating method of the memory device S10 may include storing previous output temperature data as first temperature data in a first buffer (operation S11). For example, temperature data of T2 output between the sixth time point t6 and the eighth time point t8 of the delayed clock signal DCLK corresponding to the third period P3 of the clock signal CLK may be stored in the third buffer 333.

The operating method of the memory device S10 may include, in operation S12, storing input temperature data as second temperature data in a second buffer 332. For example, the second buffer 332 may store the temperature data of Tnoise input during the second period P2 of the clock signal CLK during the third period P3.

The operating method of the memory device S10 may include storing input temperature data as third temperature data in a third buffer (operation S13). For example, the first buffer 331 may store the temperature data of Tnoise input during the third period P3 subsequent to the second period P2 of the clock signal CLK during the third period P3.

The operating method of the memory device S10 may include, in operation S14, comparing the magnitudes of first temperature data, second temperature data, and third temperature data. For example, the comparison circuit 336 may compare the magnitudes of the temperature data of Tnoise stored in the first buffer 331, the temperature data of T2 stored in the second buffer 332, and the previous output temperature data of T2 stored in the third buffer 333 during the fourth period P4 of the clock signal CLK.

The operation S14 of comparing the magnitudes of the first temperature data, the second temperature data, and the third temperature data may include comparing the magnitudes of the second temperature data and the third temperature data, and subsequently comparing the magnitudes of the first temperature data and the third temperature data. That is, the comparison circuit 336 may first compare the magnitudes of the temperature data of Tnoise stored in the first buffer 331 and the temperature data of T2 stored in the second buffer 332, and subsequently compare the magnitudes of the previous output temperature data of T2 stored in the third buffer 333 and the temperature data of Tnoise stored in the first buffer 331.

The operating method of the memory device S10 may include outputting a selection signal based on a comparison result (operation S15). For example, the comparison circuit 336 may compare the magnitudes of the temperature data of T2 stored in the first buffer 331 and the temperature data of T1 stored in the second buffer 332 during the third period P3 of the clock signal CLK, and as described above, since the difference between the magnitudes of the two temperature data is less than or equal to a predetermined threshold value, a selection signal SEL of low level may be output.

Alternatively, the comparison circuit 336 may compare the magnitudes of the temperature data of Tnoise stored in the first buffer 331 and the temperature data of T2 stored in the second buffer 332 during the fourth period P4 of the clock signal CLK, and since the difference between the magnitudes of the two temperature data is greater than a predetermined threshold value as described above, the comparison circuit 336 may subsequently compare the magnitudes of the temperature data of Tnoise stored in the first buffer 331 and the previous output temperature data of T2 stored in the third buffer 333.

As described above, since the difference between the magnitudes of the temperature data of Tnoise stored in the first buffer 331 and the previous output temperature data stored in the third buffer 333 is greater than a predetermined threshold value, the comparison circuit 336 may output a selection signal SEL of high level.

The operating method S10 of the memory device may include, in operation S16, outputting current output temperature data based on the selection signal. For example, the multiplexer 337 may output temperature data stored in the first buffer 331 or previous output temperature data stored in the third buffer 333 as current output temperature data based on the signal level of the selection signal SEL output from the comparison circuit 336.

The outputting of the current output temperature data based on the selection signal in operation S16 may include outputting the temperature data stored in the first buffer 331 as the current output temperature data based on the selection signal SEL being at a low level, and outputting the previous output temperature data as the current output temperature data based on the selection signal SEL being at a high level.

For example, based on the selection signal SEL being at the low level output from the comparison circuit 336 during the third period P3 of the clock signal CLK, the multiplexer 337 may output the temperature data of T2 stored in the first buffer 331 as the current output temperature data.

As another example, based on the selection signal SEL being at the high level output from the comparison circuit 336 during the fourth period P4 of the clock signal CLK, the multiplexer 337 may output the previous output temperature data of T2 stored in the third buffer 333 as the current output temperature data.

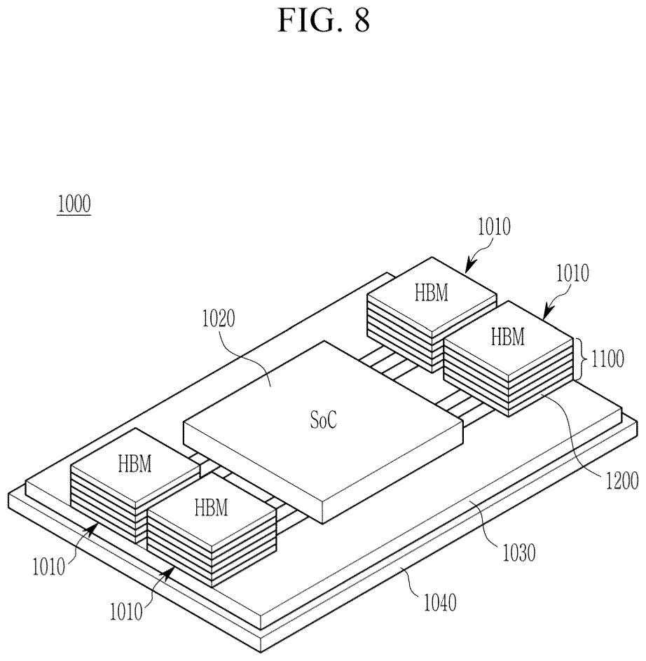

FIG. 8 is a perspective view of a semiconductor device, according to an embodiment of the present disclosure.

Referring to FIG. 8, a semiconductor device 1000 may be and/or may include a semiconductor package, which may be and/or may include a memory module including at least one memory device 1010 and a system-on-chip 1020 mounted on a package substrate 1040, such as, but not limited to, a printed circuit board (PCB). In some embodiments, the memory device 1010 may be a memory device as described with reference to FIGS. 1 to 7.

An interposer 1030 may optionally be further provided on the package substrate 1040. The memory device 1010 may be formed as a chip-on-chip (CoC). The memory device 1010 may include a memory die 1100 including at least one memory die stacked on a logic die 1200. The memory die 1100 and the logic die 1200 may be connected to each other by through-silicon via.

Each of the memory dies 1100 may include noise removal circuit as described with reference to FIGS. 3 through 7. Each memory die 1100, according to an embodiment of the present disclosure, may output temperature data with noise removed through a noise removal circuit, even if noise is included in temperature data measured through an internal temperature sensor.

Additionally, each memory die 1100, according to an embodiment of the present disclosure, may output the most recently input temperature data as output temperature data corresponding to input temperature data including noise. Additionally, through the delay circuit included in the noise removal circuit, output of temperature data with reduced delay, when compared to related memory devices, may be obtained.

Based on the temperature data received from the memory die 1100, the logic die 1200 may control the temperature of each memory die 1100.

In some embodiments, the memory device 1010 may be a high bandwidth memory (HBM) having a bandwidth of 500 gigabytes per second (GB/sec) to 1 terabyte per second (TB/sec), or more. However, embodiments of the present disclosure may not be limited thereto, and the memory device 1010 may support other bandwidth ranges.

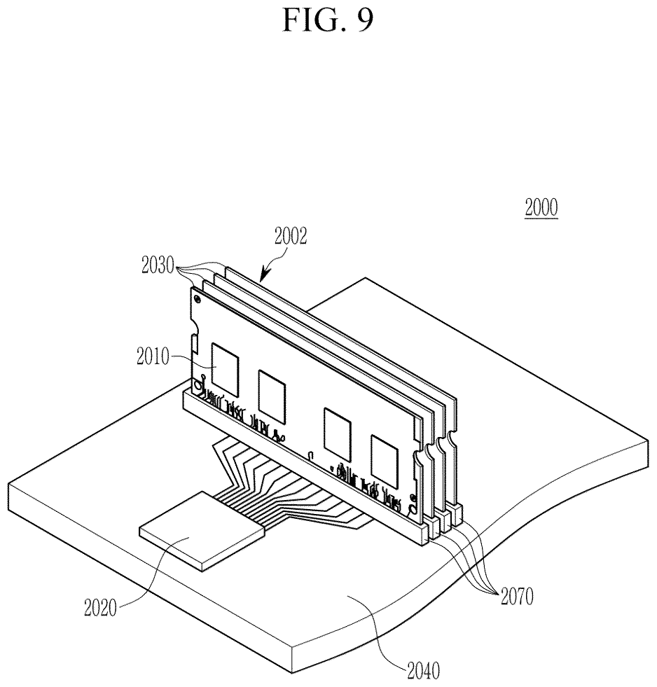

FIG. 9 is a perspective view of a semiconductor device, according to an embodiment of the present disclosure.

Referring to FIG. 9, a semiconductor device 2000 may be and/or may include a dual in-line memory module (DIMM) system in which semiconductor chips may be mounted on both sides of a printed circuit board, and may include a memory module 2002 including at least one PCB 2030 and a memory controller 2020. A memory controller 2020 may be mounted on the main board 2040, and the PCB 2030 may be electrically connected to the main board 2040 through a plurality of connection sockets.

The memory device 2010 may be formed chip-on-chip and mounted on both sides of the PCB 2030. The memory controller 2020 and the memory device 2010 may be electrically connected via a bus within the PCB 2030 and the main board 2040. In some embodiments, the memory device 2010 may include a stacked structure of memory dies and logic dies. In some embodiments, the memory device 2010 may be and/or may include a memory device as described with reference to FIGS. 3 to 7.

The memory device 2010, according to an embodiment of the present disclosure, may include a noise removal circuit as described with reference to FIGS. 3 to 7. The memory device 2010, according to an embodiment of the present disclosure, may output temperature data with noise removed through a noise removal circuit even if noise is included in temperature data measured through an internal temperature sensor.

Additionally, the memory device 2010, according to an embodiment of the present disclosure, may output the most recently input temperature data as output temperature data corresponding to input temperature data including noise. Additionally, through the delay circuit included in the noise removal circuit, output of temperature data with a reduced delay, when compared to related memory devices, may be obtained.

In some embodiments, the memory device 2010 may be a high bandwidth memory (HBM) of 500 GB/sec to 1 TB/sec, or more. However, embodiments of the present disclosure may not be limited thereto, and the memory device 2010 may support other bandwidth ranges

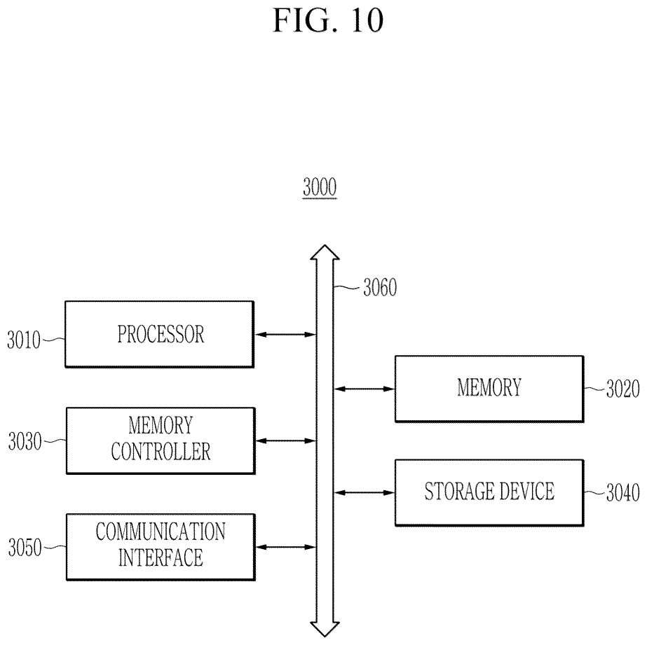

FIG. 10 is a block diagram of a computing device, according to an embodiment of the present disclosure.

Referring to FIG. 10, a computing device 3000 may include a processor 3010, a memory 3020, a memory controller 3030, a storage device 3040, a communication interface 3050, and a bus 3060. The computing device 3000 may further include other general-purpose components.

The processor 3010 may control the overall operation of each component of the computing device 3000. The processor 3010 may be implemented as at least one of various processing units such as, but not limited to, a central processing unit (CPU), an application processor (AP), a graphics processing unit (GPU) or the like.

The memory 3020 may store various data and/or commands. The memory 3020 may be implemented as a memory device described with reference to FIGS. 3 to 7.

The memory device 3020, according to an embodiment of the present disclosure, may include a noise removal circuit as described with reference to FIGS. 3 to 7. The memory device 3020, according to an embodiment of the present disclosure, may output temperature data with noise removed through a noise removal circuit even if noise is included in temperature data measured through an internal temperature sensor.

Additionally, the memory device 3020, according to an embodiment of the present disclosure, may output the most recently input temperature data as output temperature data corresponding to input temperature data including noise. Additionally, through the delay circuit included in the noise removal circuit, the memory device 3020 may output temperature data with a reduced delay when compared to related memory devices.

The memory controller 3030 may control the transfer of data and/or commands to and/or from the memory 3020. In some embodiments, the memory controller 3030 may be provided as a separate chip from the processor 3010. In some embodiments, the memory controller 3030 may be provided as an internal component of the processor 3010.

The storage device 3040 may non-temporarily store programs and/or data. In some embodiments, the storage device 3040 may be implemented as non-volatile memory. The communication interface 3050 may support wired and/or wireless communication (e.g., Internet) of the computing device 3000. Additionally, the communication interface 3050 may support various communication methods other than Internet communication. The bus 3060 may provide communication between components of the computing device 3000. The bus 3060 may include at least one type of bus depending on the communication protocol between the components.

In some embodiments, each component or a combination of two or more components described with reference to FIGS. 1 through 7 may be implemented as a digital circuit, a programmable or non-programmable logic device or array, an application specific integrated circuit (ASIC), or the like.

Although the embodiments of the present disclosure have been described in detail above, the scope of the present disclosure is not limited thereto, and various modifications and improvements made by those skilled in the art using the basic concept of the present disclosure defined in the following claims also fall within the scope of the present disclosure.

What is claimed is:

1. A memory device, comprising:
a first buffer configured to store input temperature data for a memory cell as first temperature data based on a clock signal, and to output the first temperature data;
a second buffer configured to receive and to store the first temperature data from the first buffer based on the clock signal, and to output the first temperature data as second temperature data;
a delay circuit configured to output a delayed clock signal generated by delaying the clock signal;
a third buffer configured to output inputted third temperature data as output temperature data based on the delayed clock signal; and
a filter circuit configured to remove noise from the input temperature data based on the first temperature data, the second temperature data, and the third temperature data.

2. The memory device of claim 1, wherein the filter circuit comprises:
a comparison circuit configured to compare a first magnitude of the first temperature data, a second magnitude of the second temperature data, and a third magnitude of the third temperature data, and to output a selection signal based on a result of the comparison; and
a multiplexer configured to output, to the third buffer, at least one of the first temperature data or the third temperature data, based on the selection signal.

3. The memory device of claim 2, wherein the comparison circuit is further configured to:
compare the first magnitude of the first temperature data with the second magnitude of the second temperature data; and
subsequently compare the first magnitude of the first temperature data with the third magnitude of the third temperature data.

4. The memory device of claim 2, wherein the comparison circuit is further configured to:
output the selection signal at a low level based on a difference between the first magnitude of the first temperature data and the second magnitude of the second temperature data being less than or equal to a predetermined threshold value.

5. The memory device of claim 4, wherein the comparison circuit is further configured to:
output the selection signal at a high level based on a difference between the first magnitude of the first temperature data and the third magnitude of the third temperature data being greater than the predetermined threshold value.

6. The memory device of claim 4, wherein the comparison circuit is further configured to:
output the selection signal at the low level based on a difference between the first magnitude of the first temperature data and the third magnitude the third temperature data being less than or equal to the predetermined threshold value.

7. The memory device of claim 4, wherein the predetermined threshold value has a size of four (4) bits.

8. The memory device of claim 5, wherein the multiplexer is further configured to:
output the first temperature data based on the selection signal being at the low level.

9. The memory device of claim 5, wherein the multiplexer is further configured to:
output the third temperature data based on the selection signal being at the high level.

10. The memory device of claim 6, wherein the multiplexer is further configured to:
output the first temperature data based on the selection signal being at the low level.

11. The memory device of claim 1, wherein the input temperature data has a size of eight (8) bits.

12. The memory device of claim 1, wherein the first buffer is further configured to output the first temperature data during a first period of the clock signal, and
wherein the second buffer is further configured to output the second temperature data during a second period following the first period of the clock signal.

13. The memory device of claim 1, wherein the delay circuit is further configured to delay the clock signal within a half period of the clock signal.

14. The memory device of claim 1, wherein the first buffer comprises a first flip-flop, and
wherein the second buffer comprises a second flip-flop.

15. The memory device of claim 1, wherein the third buffer comprises a latch.

16. A method of operating a memory device, comprising:
storing, as first temperature data in a first buffer, previous output temperature data for a memory cell;
storing, as second temperature data in a second buffer, first input temperature data of the memory cell inputted during a first period of a clock signal;
storing, as third temperature data in a third buffer, second input temperature data of the memory cell inputted during a second period subsequent to the first period of the clock signal;
comparing a first magnitude of the first temperature data, a second magnitude of the second temperature data, and a third magnitude of the third temperature data;
outputting a selection signal based on the comparing; and
outputting, as current output temperature data, at least one of the first temperature data or the third temperature data based on the selection signal, the current output temperature data being synchronized to a delayed clock signal generated by delaying the clock signal.

17. The method of claim 16, wherein the comparing of the first magnitude, the second magnitude, and the third magnitude comprises:
comparing the second magnitude of the second temperature data with the third magnitude of the third temperature data; and
subsequently comparing the first magnitude of the first temperature data with the third magnitude of the third temperature data.

18. The method of claim 17, wherein the outputting of the selection signal comprises:
outputting the selection signal at a low level based on a difference between the second magnitude of the second temperature data and the third magnitude of the third temperature data being less than or equal to a predetermined threshold value; and
outputting the selection signal at a high level based on a difference between the first magnitude of the first temperature data and the third magnitude of the third temperature data being greater than the predetermined threshold value.

19. The method of claim 18, wherein the outputting of the at least one of the first temperature data or the third temperature data comprises:
outputting the third temperature data as the current output temperature data based on the selection signal being at the low level; and
outputting the first temperature data as the current output temperature data based on the selection signal being at the high level.

20. A memory device, comprising:
a memory die comprising:
a plurality of memory cells; and
a noise removal circuit configured to:
compare a third magnitude of previous output temperature data of the plurality of memory cells, a first magnitude of first input temperature data of the plurality of memory cells inputted during a first period of a clock signal, and a second magnitude of second input temperature data of the plurality of memory cells inputted during a second period subsequent to the first period of the clock signal; and
output, as current output temperature data of the plurality of memory cells, at least one of the previous output temperature data or the second input temperature data, based on a delayed clock signal generated by delaying the clock signal; and
a logic die stacked with the memory die in a first direction and configured to control a temperature of the memory die based on the current output temperature data provided using a through-silicon via at least partially penetrating the memory die in the first direction.
